(19) United States
(12) Patent Application Publication
(10) Pub. No.: US 2017/0170080 A1
(43) Pub. Date: Jun. 15, 2017

(54) MATERIAL THICKNESS DEVICE AND METHOD

(71) Applicant: Intel Corporation, Santa Clara, CA (US)

(72) Inventors: Darko Grujicic, Chandler, AZ (US); Nilanjan Ghosh, Chandler, AZ (US); Marcel A. Wall, Chandler, AZ (US); Deepak Goyal, Phoenix, AZ (US)

(73) Assignee: Intel Corporation, Santa Clara, CA (US)

(21) Appl. No.: 14/968,401

(22) Filed: Dec. 14, 2015

(51) Int. Cl. H01L 21/66; H01L 21/288; H01L 21/285; C23C 14/54; H01L 21/67; C23C 18/16; C23C 14/34; H01L 21/48; H01L 21/3213

(52) U.S. Cl. CPC H01L 22/26; H01L 21/4846; H01L 21/288; H01L 21/2855; H01L 21/32133; H01L 21/67253; C23C 18/1633; C23C 14/34; C23C 14/542

(57) ABSTRACT

A material thickness adjustment device and associated methods are shown. Material thickness adjustment devices and methods shown include eddy current measurement to determine material thickness during a deposition or removal operation. Feedback from the measured thickness may then be applied to adjust one or more processing parameters to meet a desired thickness.

### TECHNICAL FIELD

Embodiments described herein generally relate to thickness control of conductors on a substrate. Specifically, example embodiments described herein may be used to control metallic layer or metallic trace deposition or removal from a chip package substrate.

### BACKGROUND

Accurately controlling conductor thickness is a key step for process control and prevention of yield loss during substrate process development. It is desirable to have predictable film deposition and/or removal from substrates, such as organic substrates. Currently there is no method that provides a real time feedback loop to control the deposition process of metal film on highly rough substrates, such as organic substrates.

### BRIEF DESCRIPTION OF THE DRAWINGS

FIG. 1 is a cross section of a chip package in accordance with some embodiments of the invention.

FIG. 2 is a flow diagram of an example method of depositing a conductor in accordance with some embodiments of the invention.

FIG. 3 is a flow diagram of an example method of reducing a conductor in accordance with some embodiments of the invention.

FIG. 4 is an illustration of an example parameter adjustment in accordance with some embodiments of the invention.

FIG. 5 is an illustration of selected components of a conductor material coating adjustment device in accordance with some embodiments of the invention.

FIG. 6 is a block diagram of a conductor material coating adjustment device in accordance with some embodiments of the invention.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Although the present disclosure uses substrate elements of semiconductor chip packages, and their method of manufacture as an example, the invention is not so limited. Examples of the present invention may be used in any technology where addition or subtraction of a conductor onto a substrate is controlled. Other example technologies where embodiments of the present invention may be used include, but are not limited to, conductor deposition on silicon, conductor deposition on photovoltaic devices, and conductor deposition on transition elements, such as interposers, etc.

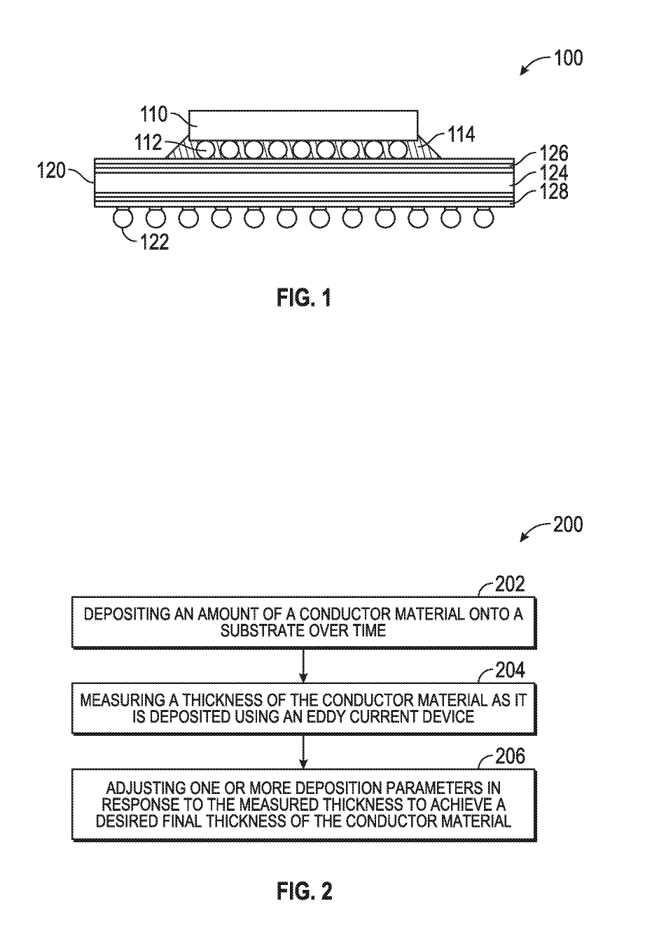

FIG. 1 shows a cross-sectional representation of an IC package 100. In embodiments where the IC die is a processor die, the IC package can be termed a processor assembly. IC package 100 includes an IC die 110 mounted in “flip-chip” orientation with its active side facing downward to couple with an upper surface of a substrate 120, through interconnections 112 such as solder balls or bumps. In one example, the interconnections 112 may be surrounded by an underfill 114.

The substrate 120 also shows a second number of first level interconnections 122 on its opposite surface for mating with additional packaging structures such as boards (not shown). In one example, the substrate 120 may include a core 124. In other examples, the substrate 120 may be a coreless substrate (not shown). In one example, the substrate 120 includes a number of build-up layers 126 adjacent to the die 110. The build-up layers 126 may include conductive traces and dielectric layers to electrically isolate the conductive traces. In one example, the build-up layers 126 are deposited sequentially to form complex electrical routing between the interconnections 112 of the die 110 and the first level interconnections 122 on another side of the substrate 120.

In the example of FIG. 1, the core 124 may include both build-up layers 126 on a first side of the core 124, and build-up layers 128 on a second side of the core 124. In one example method of manufacturing, build-up layers 126 and build-up layers 128 are formed concurrently on both the first side and the second side of the core 124.

One or more methods described below may be used to control a thickness of a conductor layer on substrate, for example package substrate 120 as described above. In one example, one or more methods described below may be used to control thickness of a conductor layer or conductor trace, etc. as a part of build-up layers 126 and/or 128. Other substrates apart from substrate 120, and other components of IC package 100 are contemplated to be within the scope of the invention.

FIG. 2 shows a flow diagram of an example method according to an embodiment of the invention. In operation 202, an amount of a conductor material is deposited onto a substrate over time. In operation 204, a thickness of the conductor material is measured as it is deposited using an eddy current device. In operation 206, one or more deposition parameters are adjusted in response to the measured thickness to achieve a desired final thickness of the conductor material.

Methods described in the present disclosure can be used with a number of different deposition techniques and devices. In one example, a deposition technique includes electroless deposition. In one example, a deposition technique includes electroplating. In one example, a deposition technique includes sputtering. Although electroless deposition, electroplating, and sputtering are mentioned as examples, the invention is not so limited.

A thickness of any number of conductor materials can be measured using devices and methods described in the present disclosure. In one example, a thickness of a copper, or copper containing layer is measured. In one example, a thickness of an aluminum, or aluminum containing layer is measured. In one example, a thickness of a gold, or gold containing layer is measured. Although copper, aluminum, and gold are mentioned as examples, the invention is not so limited. Any conductor material that functions with eddy currents may be used with embodiments of the present invention.

Depending on the deposition method being used, any number of different deposition parameters may be adjusted in response to the real-time thickness information being provided by the eddy current sensor or sensors. In one example, an adjusted deposition parameter includes adjusting a deposition time. In one example, an adjusted deposition parameter includes voltage. In one example, an adjusted deposition parameter includes sputter rate. In one example, an adjusted deposition parameter includes changing a chemistry of an electroless plating bath.

In one example of eddy current measurement, a coil of conductive wire is excited with an alternating electrical current. This wire coil produces an alternating magnetic field around itself in the direction ascertained by the right hand rule. The magnetic field oscillates at the same frequency as the current running through the coil. When the coil approaches a conductive material to be measured, eddy currents are induced in the material, and are opposed to the currents in the coil.

Characteristics of the eddy currents in the material to be measured change as a function of material thickness. A change in eddy current and a corresponding change in phase and amplitude can be detected by measuring the impedance changes in the coil, which can be correlated to material thickness. In one example, variable frequency alternating current generates an alternating magnetic field in the sample, which in turn generates an alternating frequency electric field. By measuring the impedance of the thickness of a conductor layer can be measured.

In addition, in one example a thickness of a non-conducting layer or dielectric layer that is either directly adjacent, or in close proximity to a conductor layer can be measured using eddy current sensing. When a conducting layer is present near a dielectric layer, the conducting layer will still generate eddy currents when they are induced by the eddy current probe. The addition of a dielectric layer in proximity to the conductor layer will affect the eddy current characteristics. The difference in eddy current characteristics with the addition of a dielectric layer can be calibrated and used to determine the thickness of the dielectric layer.

Eddy current sensing provides a number of advantages. In one example, use of eddy current sensing devices provides a non-destructive method of measuring thickness of a conductor material. In one example, use of eddy current sensing devices provides a non-contact method of measuring thickness of a conductor material. In one example, use of eddy current sensing devices provides a real-time method of measuring thickness of a conductor material. Real-time metrology allows adjustment of parameters that affect deposition rate, and allows for more accurate final thickness.

In one example, eddy current sensing can be used to measure an average thickness of rough surfaces. In one example, using variable frequency alternating eddy current, noncontact thickness measurement of highly rough surfaces are possible with micro-meter resolution. In one example, using variable frequency alternating eddy current, noncontact thickness measurement of highly rough surfaces are possible with sub ten nanometer resolution.

Devices and methods described using eddy current sensing are easy to implement into existing process tooling. Devices and methods described using eddy current sensing may eliminate the need for dedicated test panels thereby significantly reducing cost and time of process development.

In addition to measuring a thickness of a conductor during a deposition operation, devices and methods described in the present disclosure can also be used to measure a changing thickness during a material removal operation, such as etching.

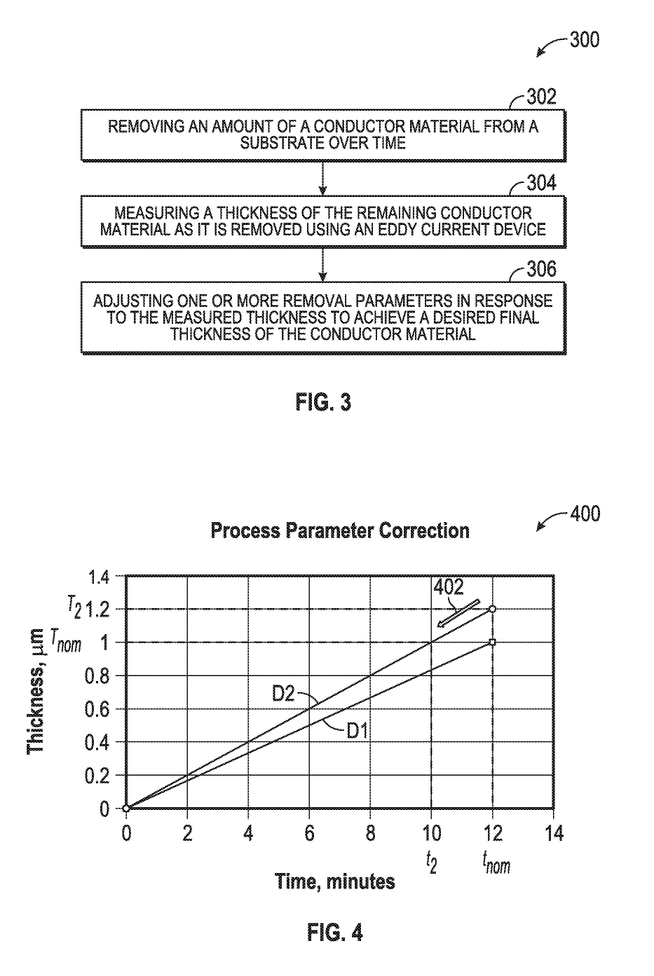

FIG. 3 shows a flow diagram of an example method according to an embodiment of the invention. In operation 302, an amount of a conductor material is removed from a substrate over time. In operation 304, a thickness of the remaining conductor material is measured as it is removed using an eddy current device. In operation 306, one or more removal parameters is adjusted in response to the measured thickness to achieve a desired final thickness of the conductor material.

Methods described in the present disclosure can be used with a number of different material removal techniques and devices. In one example, a material removal technique includes chemical etching. In one example, a material removal technique includes plasma etching. In one example, a material removal technique includes ablation. Although chemical etching, plasma etching, and ablation are mentioned as examples, the invention is not so limited.

Similar to deposition, as described above, and number of conductor materials may be used with devices and methods described. Examples include, but are not limited to, copper, aluminum, gold, etc.

Also similar to deposition, in a material removal operation, depending on the method being used, any number of different removal parameters may be adjusted in response to the real-time thickness information being provided by the eddy current sensor or sensors. In one example, an adjusted deposition parameter includes adjusting an etching time. In one example, an adjusted removal parameter includes voltage. In one example, an adjusted removal parameter includes ablation rate. In one example, an adjusted deposition parameter includes changing a chemistry of an etching bath.

FIG. 4 shows a graph of an adjustment to an example deposition parameter using a formula determined using eddy current measurement. In FIG. 4, a first deposition time tₙₒₘ is projected to form a conductor layer of thickness Tₙₒₘ. After real-time measurement using eddy current techniques as described above, a deposition time is adjusted from tₙₒₘ to t₂. The resulting thickness predicted from the parameter adjustment is shown at arrow 402, where the projected thickness changes from T₂ back to the desired Tₙₒₘ.

Electroless metal thickness is determined by the product design. The thickness of deposited metal film is a direct function of the panel dwell time in the deposition tool:

Tₙₒₘ=D₁×tₙₒₘ

Where: Tₙₒₘ is the metal thickness, D1 is the deposition rate and tₙₒₘ is the time that the panel is being processed in the deposition tool. In one example, eddy current systems as described enable measurement of the metal film thickness as soon as the panels are processed and are being unloaded from the tool. Measured thickness will be then be used for algorithmic correction of the deposition time, according to the following calculation:

t₂=Tₙₒₘ/T₂×tₙₒₘ

Where: Tₙₒₘ is desired metal thickness, T₂ is the actual measured metal thickness and t₂ is the new deposition time. The parameter t₂ is fed back to the deposition tool software to be applied to correct for thickness deviation from the target.

Although the above equations are shown as an example to calculate parameter changes for electroless deposition, the invention is not so limited. Other deposition or material removal techniques (sputtering, chemical etching, etc.) may require different equations to account for different relationships between a chosen parameter and a change in material deposition/removal rate.

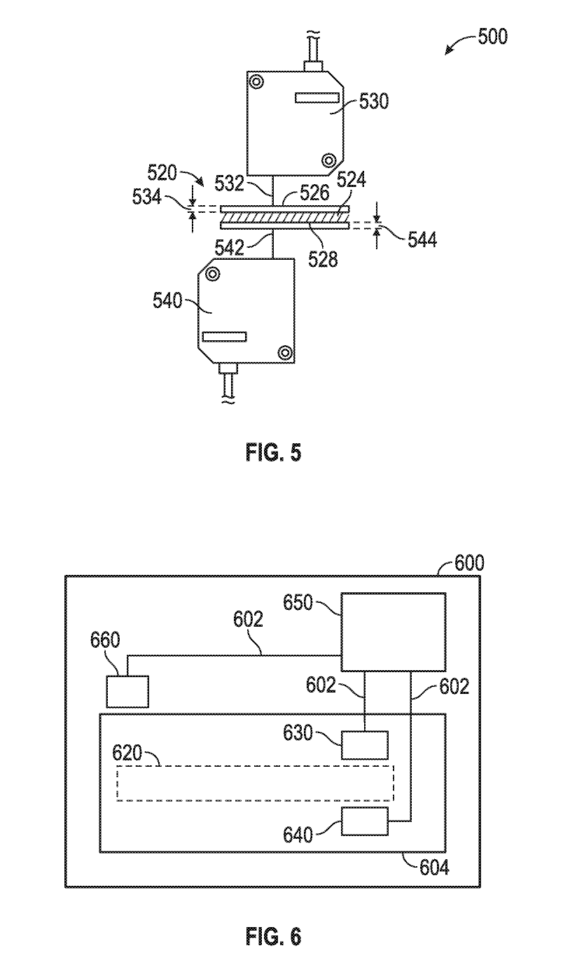

FIG. 5 shows a portion of a conductor material coating adjustment device according to an embodiment of the invention. In the example shown, a substrate 520 includes a first build-up layer or series of layers 526. The substrate 520 also includes a second build-up layer or series of layers 528.

In the example shown, the substrate 520 is a cored substrate with core 524, although the invention is not so limited. Coreless substrates may be measured with devices and methods described. Also, although FIG. 5 shows two sided measurement, devices and methods described in the present disclosure may be used to measure a single sided substrate.

FIG. 5 shows a first eddy current probe 530 and a second eddy current probe 540. A field 532 from the first eddy current probe 530 is shown measuring a first thickness 534 of one or more layers in 526. Also, a field 542 from the second eddy current probe 540 is shown measuring a second thickness 544 of one or more layers in 528. As discussed above, although a two sided substrate deposition is shown as an example in FIG. 5, single sided measurement is also within the scope of the invention.

FIG. 6 shows a block diagram representation of a conductor material coating adjustment device 600 according to one example of the invention. A substrate 620 is shown located within a processing chamber 604. A first eddy current probe 630 and a second eddy current probe 640 are shown on opposing sides of the substrate 620. As noted above, single sided measurement examples are also within the scope of the invention. A feedback circuit 650 is shown coupled to the eddy current probes 630, 640 by means of circuitry 602. A conductor material coating thickness adjustor 660 is also shown coupled to the feedback circuit 650 using circuitry 602. As discussed in examples above, the conductor material coating thickness adjustor 660 choice depends on the deposition or removal technique being employed.

To better illustrate the methods and device disclosed herein, a non-limiting list of embodiments is provided here:

Example 1 includes a method of depositing a conductor material. The method includes depositing an amount of a conductor material to a substrate over time, measuring a thickness of the conductor material as it is deposited using an eddy current device, and adjusting one or more deposition parameters in response to the measured thickness to achieve a desired final thickness of the conductor material.

Example 2 includes the method of example 1, wherein depositing an amount of a conductor material includes depositing an amount of copper.

Example 3 includes the method of any one of examples 1-2, wherein depositing an amount of a conductor material includes electroless plating the amount of the conductor material.

Example 4 includes the method of any one of examples 1-3, wherein depositing an amount of a conductor material includes sputtering the amount of the conductor material.

Example 5 includes the method of any one of examples 1-4, wherein adjusting one or more deposition parameters includes adjusting a deposition time duration.

Example 6 includes the method of any one of examples 1-5, wherein adjusting one or more deposition parameters includes adjusting a sputter rate.

Example 7 includes the method of any one of examples 1-6, wherein measuring a thickness of the conductor material includes measuring on a micro-meter order of magnitude.

Example 8 includes a method of reducing a conductor material. The method includes removing an amount of a conductor material from a substrate over time, measuring a thickness of the remaining conductor material as it is removed using an eddy current device, and adjusting one or more removal parameters in response to the measured thickness to achieve a desired final thickness of the conductor material.

Example 9 includes the method of example 8, wherein removing an amount of a conductor material includes etching the amount of the conductor material.

Example 10 includes the method of any one of examples 8-9, wherein adjusting one or more removal parameters includes adjusting an etching duration.

Example 11 includes the method of any one of examples 8-10, wherein adjusting one or more removal parameters includes adjusting an etchant chemistry.

Example 12 includes the method of any one of examples 8-11, wherein removing an amount of a conductor material includes removing an amount of copper.

Example 13 includes a conductor material coating adjustment device, including, a conductor material coating thickness adjustor, an eddy current thickness measurement device, and a feedback circuit adapted to use data from the eddy current thickness measurement device to adjust one or more parameters of the conductor material coating thickness adjustor.

Example 14 includes the conductor material coating adjustment device of example 13, wherein the adjustor includes a deposition device.

Example 15 includes the conductor material coating adjustment device of any one of examples 13-14, wherein the adjustor includes an electroless deposition device.

Example 16 includes the conductor material coating adjustment device of any one of examples 13-15, wherein the adjustor includes a sputter deposition device.

Example 17 includes the conductor material coating adjustment device of any one of examples 13-16, wherein the adjustor includes a removal device.

Example 18 includes the conductor material coating adjustment device of any one of examples 13-17, wherein the feedback circuit is adapted to adjust a time duration of the conductor material coating thickness adjustor.

Example 19 includes the conductor material coating adjustment device of any one of examples 13-18, wherein the feedback circuit is adapted to adjust an electroless plating chemistry of the conductor material coating thickness adjustor.

Example 20 includes the conductor material coating adjustment device of any one of examples 13-19, wherein the conductor material coating thickness adjustor includes a copper coating thickness adjustor.

These examples are intended to provide non-limiting examples of the present subject matter—they are not intended to provide an exclusive or exhaustive explanation. The detailed description above is included to provide further information about the present devices, and methods.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1-12. (canceled)

13. A conductor material coating adjustment device, comprising:
a conductor material coating thickness adjustor;
an eddy current thickness measurement device; and
a feedback circuit adapted to use data from the eddy current thickness measurement device adjust one or more parameters of the conductor material coating thickness adjustor.

14. The conductor material coating adjustment device of claim 13, wherein the adjustor includes a deposition device.

15. The conductor material coating adjustment device of claim 14, wherein the adjustor includes an electroless deposition device.

16. The conductor material coating adjustment device of claim 13, wherein the adjustor includes a sputter deposition device.

17. The conductor material coating adjustment device of claim 13, wherein adjustor includes a removal device.

18. The conductor material coating adjustment device of claim 13, wherein the feedback circuit is adapted to adjust a time duration of the conductor material coating thickness adjustor.

19. The conductor material coating adjustment device of claim 13, wherein the feedback circuit is adapted to adjust an electroless plating chemistry of the conductor material coating thickness adjustor.

20. The conductor material coating adjustment device of claim 13, wherein the conductor material coating thickness adjustor includes a copper coating thickness adjustor.
